(19) United States
(12) Patent Application Publication
(10) Pub. No.: US 2007/0096107 A1
(43) Pub. Date: May 3, 2007

(54) Semiconductor devices with dielectric layers and methods of fabricating same

(76) Inventor: Dale Marius Brown, Schenectady, NY (US)

Correspondence Address: Patrick S. Yoder;FLETCHER YODER, P.O. Box 692289, Houston, TX, 77269-2289, US

(21) Appl. No.: 11/265,919

(22) Filed: Nov. 3, 2005

(51) Int. Cl. H01L 31/0312

(52) U.S. Cl. 257/77

(57) ABSTRACT

A SiC semiconductor device with a SiC layer and an insulating layer is provided. The insulating layer may include glass or ceramic. The thermal expansion coefficient of the insulating layer may be matched to that of SiC to reduce stress at the interface. A method of processing the SiC semiconductor device is also provided.

### BACKGROUND

The invention relates generally to semiconductor devices and more particularly to silicon carbide semiconductor devices.

Silicon carbide (SiC) is a crystalline substance that can endure very high temperatures. SiC semiconductor devices can operate at temperatures in excess of 200° C. SiC metal oxide semiconductor field effect transistors (MOSFETs) are currently being investigated because of the superior material properties of SiC. The most significant of these are the wide bandgap, which is about 3 times that of Silicon, the high breakdown field, which is about 10 times that of Silicon, and a higher thermal conductivity, which is about 3 times that of Silicon. The above properties of SiC provide devices that are better suited for higher temperature operation, and better efficiency due to lower power loss. All types of sensor, logic (ICs), power control and power conditioning devices based on SiC should therefore prove to have advantages over analogous Silicon (Si) devices.

For SiC MOSFETs, the formation of a gate oxide typically involves thermal oxidation of SiC at very high temperature of about 1000° C. to about 1300° C. or higher to create a silicon oxide layer. The thermal expansion coefficients of SiC and silicon oxide (SiO₂) are markedly different. Depending on temperature and surface orientation, the thermal expansion coefficient of SiC varies from about 4.2×10⁻⁶/K to about 4.9×10⁻⁶/K, while that of Sio₂ is about 0.6×10⁻⁶/K. After oxidation, the SiC/SiO₂ interface will be considerably stressed since the SiC layer contraction upon cooling is much more than the Sio₂ layer contraction, due to the large differences in their thermal expansion coefficients.

SiC typically has a hexagonal Wurtzite crystal structure composed of large silicon atoms and small carbon atoms. This type of structure is prone to spontaneous polarization effects due to the fact that it is not cubic and that it is a compound material. The polarization of charge due to the polarization effect creates electron traps and can decrease the effective or mobile surface charge in a field effect transistor. Stress is known to produce polarization effects in Wurtzite crystals.

Further, it has been shown that the generation of interface traps is a function of mechanical strain at the semiconductor/SiO₂ interface, as has been demonstrated by studies of Si MOS devices. In particular, it is known that the generation of interface traps by Fowler-Nordheim (FN) injection is a function of the mechanical strain at the interface. FN injection may produce short mean time failure (MTF) of gate dielectrics and it requires relatively high fields of about 8MV/cm so as to provide sufficient energy to the electrons to enable them to “climb” over the semiconductor/SiO₂ barrier height.

The interface states can increase the rate of electron injection into the gate oxide when positive bias is applied to the gate electrode and may affect the reliability of the device. Electron injection such as hot electron injection produces a shift or drift in MOSFET threshold due to electron trapping in the oxide at the interface traps. When enough electrons have been trapped, the negative space charge in the oxide will pinch off the electron surface channel in a NMOSFET and it may cease to operate. It is also known that the capture rate of electrons in the SiO₂ depends on the strain in the SiO₂ film.

Another factor that affects the reliability of the device is the time dependent dielectric breakdown of the gate oxide (TDDB). A mechanism that can occur at lower fields which can lead to short TDDB is through resonance tunneling. In this case, interface traps produce electron sites at energy levels below the barrier height. Electrons can then tunnel from the semiconductor through the barrier at lower energies. Resonance tunneling is temperature dependent. As the temperature is increased, the distribution of electron energies broaden as a result of which a greater number of electrons can “match up” or be in resonance with trapping energy levels at the SiO₂ side of the interface. The tunneling current therefore increases and TDDB MTF decreases. The resonance tunneling model explains the plot of TDDB MTF versus gate voltage at lower fields than that required for FN injection, where the TDDB MTF graph of MTF versus gate voltage “bends down” and extrapolates to much shorter TDDB MTF times than a FN TDDB MTF extrapolation to nominal operational gate voltages, and is given in FIG. 1. This is especially severe for SiC MOS devices even at moderately elevated temperatures.

For a given gate voltage, the amount of charge at the semiconductor side of the gate dielectric is shared between the mobile charge in the surface channel and that in the traps. Hence, the interface traps generated by interfacial strain can reduce the amount of mobile surface charge in the transistor. Therefore, there is a need to address these issues to enhance the performance and reliability of SiC based semiconductor devices.

Accordingly, a technique is needed to address one or more of the foregoing problems in semiconductor devices, such as MOSFET devices.

### BRIEF DESCRIPTION

Briefly, in accordance with one embodiment of the present invention, a semiconductor device is fabricated with a silicon carbide layer and an insulating layer comprising glass or ceramic, over the silicon carbide layer.

In another embodiment of the present invention, a semiconductor device including a SiC layer is provided. Further, an insulating material layer is disposed over the SiC layer. A thermal expansion coefficient of the insulating material is matched to a thermal expansion coefficient of the SiC to reduce stress at a SiC layer-insulating material layer interface.

In yet another embodiment of the invention, a method of fabricating a SiC device is presented. A SiC layer is provided. An insulating layer is disposed on the SiC layer and the insulating layer comprises a glass or ceramic material.

### DRAWINGS

These and other features, aspects, and advantages of the present invention will become better understood when the following detailed description is read with reference to the accompanying drawings in which like characters represent like parts throughout the drawings, wherein:

FIG. 1 illustrates the gate current is and the time dependent dielectric breakdown (TTDB) mean time to failure (MTF) as a function of electric field E;

FIGS. 2-8 are cross-sectional views of fabrication stages of a semiconductor device in accordance with a particular embodiment of the present invention;

FIGS. 9-15 are cross-sectional views of fabrication stages of a semiconductor device in accordance with embodiments of the present invention;

FIG. 16 is a flow chart of a method of fabricating a semiconductor device in accordance with embodiments of the present invention; and

FIG. 17 is a flow chart of another method of fabricating a semiconductor device in accordance with embodiments of the present invention.

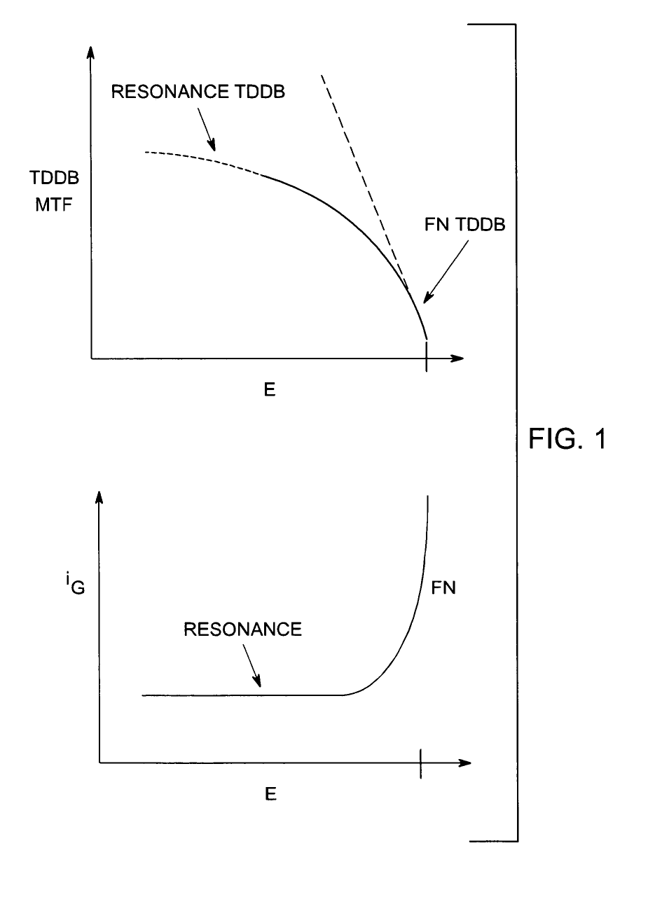

### DETAILED DESCRIPTION

It will be understood by those skilled in the art that “n-type” and “p-type” refer to the majority of charge carriers, which are present in a respective layer. For example, in n-type layers, the majority carriers are electrons, and in p-type layers, the majority carriers are holes (the absence of electrons). As used herein, n+ and n− refers to higher and lower concentration of the doping.

As used herein, the term “doped glass” indicates any composition of glass including at least one element or group in addition to silicon dioxide (SiO₂). It may be better understood by the following depiction [X:SiO₂] where X is a dopant which is typically an oxide of the element or group. In one embodiment, for example, wherein the glass comprises a phosphosilicate glass and the element comprises phosphorus, X comprises P₂O₅. The dopant, X is an element belonging to the periodic table or a compound therefrom.

For simplicity, the following description will describe fabrication of a basic SiC MOSFET device. However, those skilled in the art will appreciate that the techniques described herein may be employed in conjunction with other SiC based semiconductor devices, such as, but not limited to, integrated circuits, electrooptical devices and insulated gate bipolar transistors (IGBT). In one non-limiting example, the gate region for the IGBT contains an insulating layer with matching thermal expansion coefficient (TEC) to that of SiC.

A MOSFET is a transistor including a gate, a drain and a source. The source and drain of a typical MOSFET are made up of a semiconducting substrate material such as, Si, SiC or GaN. The gate is separated from the substrate by an insulating layer. As will be appreciated, upon application of a voltage or an electric field across the gate, the source to drain current can be controlled. The electric field induces charge in the semiconducting material at the semiconductor/insulating layer interface.

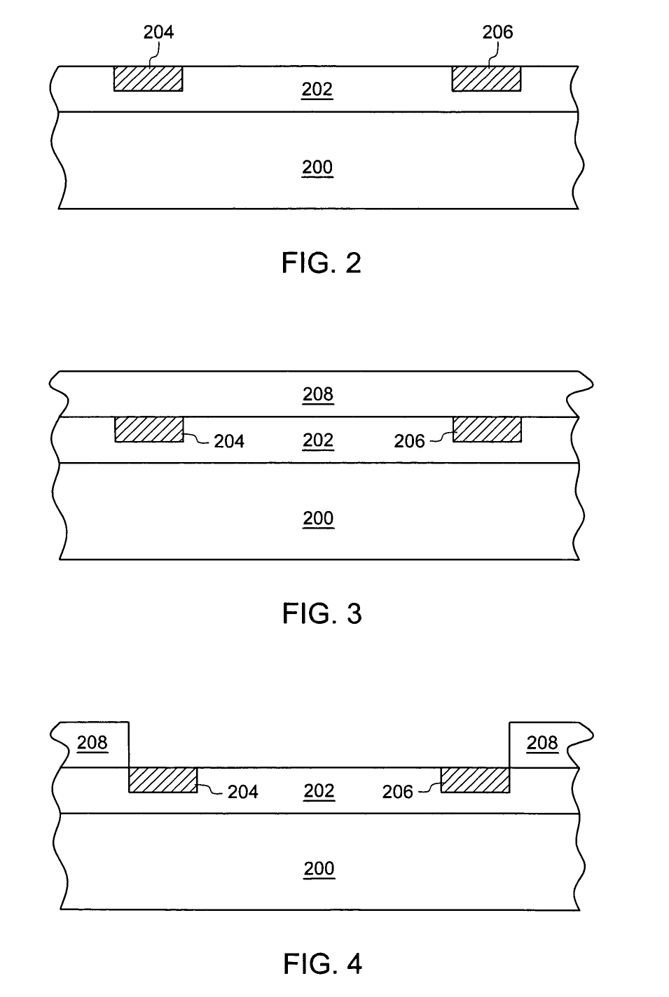

FIG. 2 depicts an initial stage in processing of a SiC MOSFET in accordance with an embodiment. The NMOSFET includes a p+ doped SiC substrate 200 which is doped with aluminum at concentrations of about 10¹⁸ cm⁻³, and a p− doped epi layer 202 epitaxially grown over the substrate with concentration of about 10¹⁴ cm⁻³ to about 10¹⁷ cm⁻³. The p− doped epi layer is about 1-2 microns in thickness. The p− doped epi layer will contain an electron channel of the NMOSFET when the surface is inverted with the application of positive gate bias. In an alternate embodiment of a PMOSFET, the substrate and the epi layer are of n-type.

Two regions of n+ doped regions 204, 206 are ion-implanted in the epi layer 202, to form source region 204 and drain region 206. The ion implantation is carried out through standard techniques known to one skilled in the art. Following ion implantation, the source region and the drain region are annealed at a temperature of about 1300° C. to about 1500° C.

A thick field oxide 208 is disposed on the epi layer 202 as shown in FIG. 3. In the illustrated example, the field oxide is disposed by chemical vapor deposition using silane and oxygen. In one embodiment, thermal expansion coefficient (TEC) of the field oxide is matched to SiC of the epi layer 202. The thick field oxide performs the function of isolating adjacent devices because the field threshold for surface inversion will be much higher than that of a thin gate oxide. The parasitic capacitance of any overlaying contact or interconnection metals, such as gate lines, will also be lower because of the thickness of the field dielectric. In one embodiment, a fraction of the field oxide is thermally grown over the epi layer.

By using photolithography and a suitable etching process a portion of the field oxide layer 208 is etched away for gate oxide formation. The source region 204 and the drain region 206 are exposed after etching as shown in FIG. 4. A thin insulating layer 210 is disposed over the exposed source region and drain region as given in FIG. 5. In this case, the insulating layer 210 is a gate oxide layer or a gate dielectric layer. The gate dielectric layer includes an oxide and may be disposed using deposition techniques such as chemical vapor deposition or thermal oxidation, for example.

As described in previous paragraphs it is desirable to reduce the interfacial stress between the gate dielectric and underlying SiC. Embodiments of the present invention address this issue by matching the thermal expansion coefficients of the gate oxide and SiC. In some embodiments of the present invention, to match the TECs, the TEC of the gate oxide is tailored to be in a range of about 2×10⁻⁶/K to about 9×10⁻⁶/K. In some other embodiments, to match the TECs, the TEC of the gate oxide is tailored to be in a range of about 3×10⁻⁶/K to about 7×10⁻⁶/K. In certain other embodiments to match the TECs, the TEC of the gate oxide is tailored to be in a range of about 4×10⁻⁶/K to about 6×10⁻⁶/K.

In the illustrated example silane (SiH₄), phosphine (PH₃), and oxygen is used to form a suitable composition of phosphosilicate glass (P₂O₅:SiO₂) to match the TEC of SiC. The TEC of these films can be as high as 9×10⁻⁶/K depending on the concentration of P₂O₅. Alternately, a gate oxide could be thermally grown and in turn a glassy layer is deposited or formed by exposure to glass forming agents or ceramic forming agents, before cooling. Annealing of this composite before cooling would transform it into a glassy layer with a higher TEC than SiO₂. The gate oxide layer may be termed as gate dielectric layer or insulating layer.

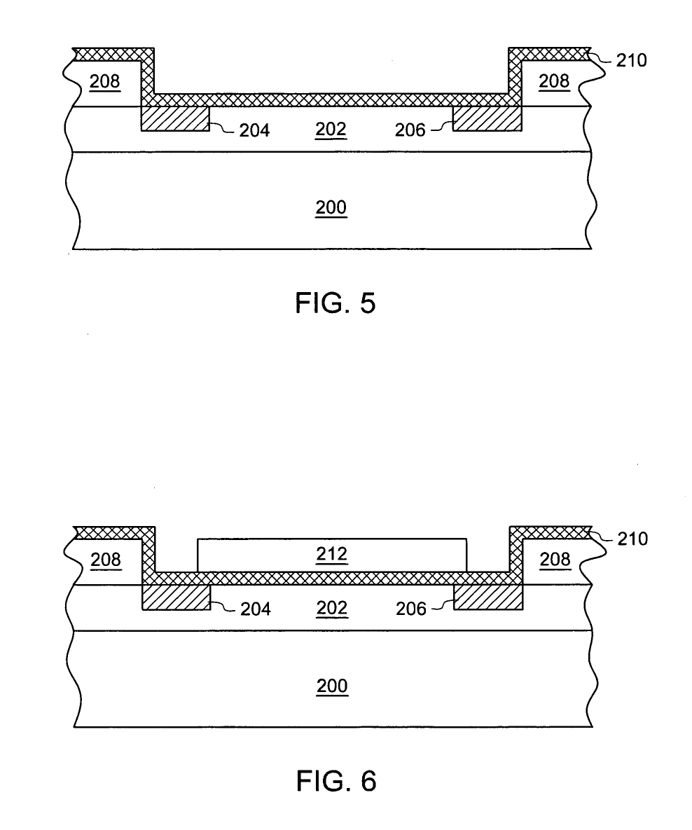

After high temperature annealing and controlled cooling, a gate electrode 212 is patterned over the gate oxide layer 210 as shown in FIG. 6. The patterning is through standard techniques of masking and etching. In the illustrated example, polysilicon is chemical vapor deposited over the gate oxide. Suitable gate electrode materials are molybdenum, tungsten, titanium silicide, molybdenum silicide, or cobalt silicide.

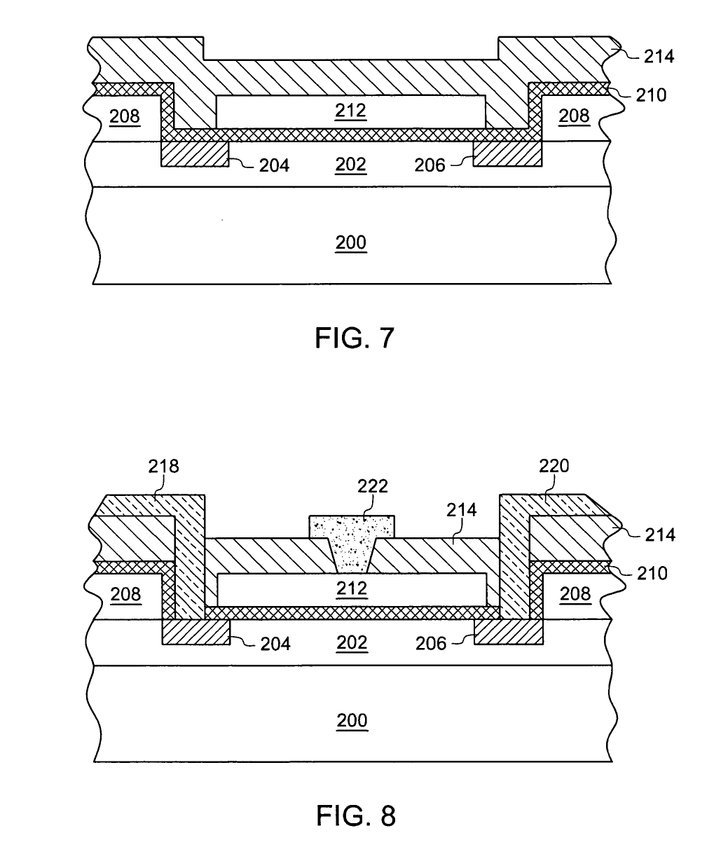

FIG. 7 shows the structure of the device after applying a passivation layer 214. The passivation layer 214 prevents mechanical damages to the device on exposure to external environment. The passivation layer in this example consists of silicon dioxide and is deposited using concentrated CVD apparatus using silane and oxygen to deposit the oxide. In one embodiment, the passivation layer includes glasses such as borosilicate glasses or phosphosilicate glasses.

Contact windows 218, 220 are formed over the source region 204 and drain region 206, respectively, as given in FIG. 8. In one embodiment, windows are formed through etching a portion of the field oxide layer, and then metal contacts (not shown in FIG. 8) are deposited over the exposed region. The metal contact is then sintered and interconnects are added as shown in the FIG. 8. Similarly, gate contact 222 is formed over a gate, extending over layers 208, 210, and 214.

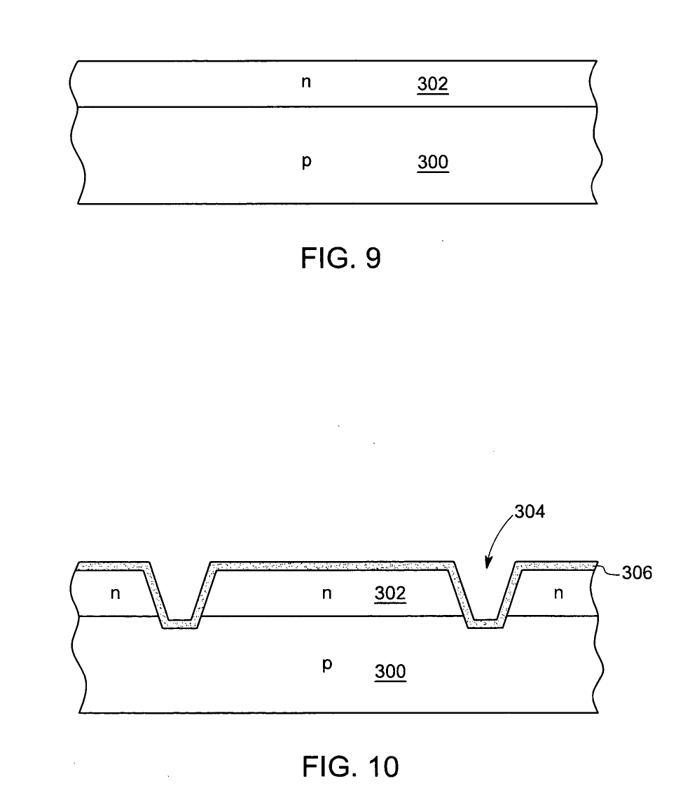

In one embodiment of the invention, a SiC MOSFET device may include a plurality of SiC layers of differing conductivities. In yet another embodiment, the silicon carbide layer includes one or more n-doped regions or p-doped regions or undoped regions or any combinations thereof. FIG. 9 depicts an example SiC device with a SiC substrate 300, which is p-doped, and a n-doped SiC layer 302 disposed over the SiC substrate. In one example, substrate 300 is formed epitaxially over a heavily doped p-type substrate. In a non-limiting example, the SiC material may be one of any number of SiC polytypes, common examples of which include 6H and 4H monocrystalline structure which may be doped with nitrogen at concentrations of about 10¹⁸ cm⁻³ to about 10²⁰ cm⁻³, to provide the n-doped SiC layer 302. The SiC p-doped substrate 300 may be obtained by doping with a dopant such as aluminum or boron, at concentrations of about 10¹⁴ cm⁻³ to about 10¹⁵ cm⁻³. The p-doped substrate or layer 300 may support a number of individual MOSFETs, as will be appreciated. However, for simplicity, the following description will focus upon the fabrication of a single MOSFET.

For the particular example shown in FIG. 10, grooves 304 having sidewalls and a base, are etched through the n-doped layer 302 and into the p-doped substrate 300. The grooves 304 define a future location for a gate structure for each SiC MOSFET device. The groove shape may vary from an annular ring to an arrangement of substantially rectangular slots depending on the desired device structure.

An insulating material layer 306 is then disposed over the entire structure, including the grooves 304, thus coating the sidewalls and the base regions of the grooves 304. The function of this insulating layer 306 is to physically separate the gate region from the source and drain regions of a MOSFET thus preventing undesirable current leakages. The insulating layer 306 may also be referred to as the gate oxide layer or the gate dielectric layer. The insulating layer 306 is usually thermally grown over the SiC layer 302 by oxidation at temperatures in the range of about 1000° C. to about 1300° C.

Subsequent to thermal oxidation and cooling, the SiC layer 302 and the insulating layer 306 develop stress at the interface of the dielectric/SiC layers. The stress at the interface may result in undesirable consequences that may affect the yield, performance and reliability. Embodiments of the present invention address this issue by matching the thermal expansion coefficients of the insulating material and SiC.

In one embodiment of the present invention, the insulating layer 306 is selected from a group of materials including, but not limited to borosilicate, phosphosilicate, and oxides of arsenic, antimony or germanium in combination with SiO₂. The insulating layer 306 may be formed over SiC layer 302 using deposition techniques such as but not limited to sputtering, chemical vapor deposition, laser assisted molecular beam deposition, or plasma enhanced chemical vapor deposition. In one embodiment, the insulating layer 306 is formed by thermal oxidation using oxygen, steam, nitric or nitrous oxides and by exposure to glass forming agents, such as phosphine, silane, oxygen or POCl₃, either during or after the thermal oxidation.

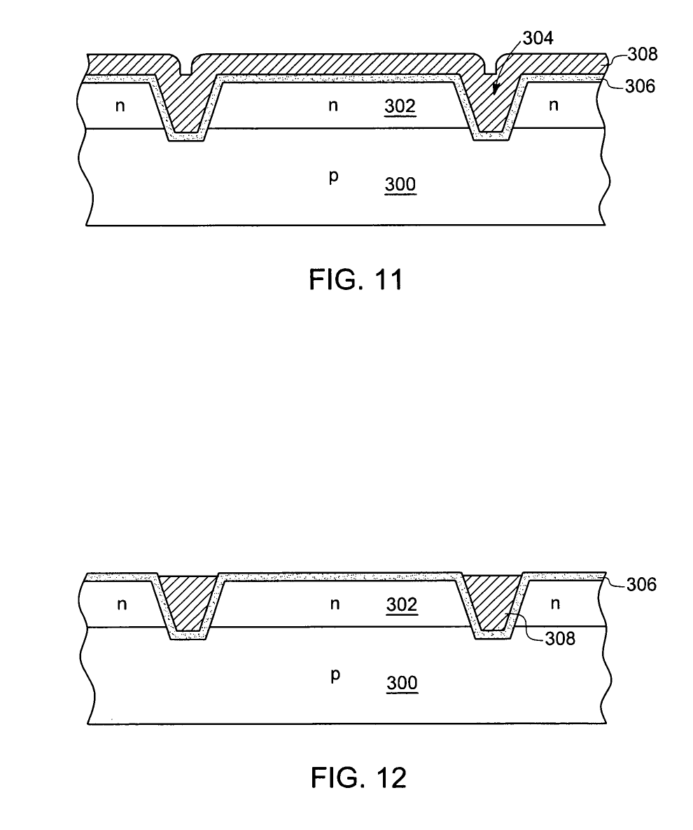

After deposition of the insulating layer 306, a conductive gate material 308 is deposited over the insulating layer 306 to substantially fill the grooves 304, as shown in FIG. 11. The conductive material 308 may be deposited using well known sputtering or chemical vapor deposition techniques, for instance. Commonly used conductive gate materials include polycrystalline silicon, aluminum, molybdenum, and tungsten. A photoresist layer is used to pattern gate and landing pads and may be patterned elsewhere to produce conductive interconnections between transistors (not shown).

FIG. 12 is a cross-sectional view of the device after etching the conductive gate material 308. The conductive gate material is removed as shown. Etching is carried out so that the conductive material is well within the grooves as shown in FIG. 12.

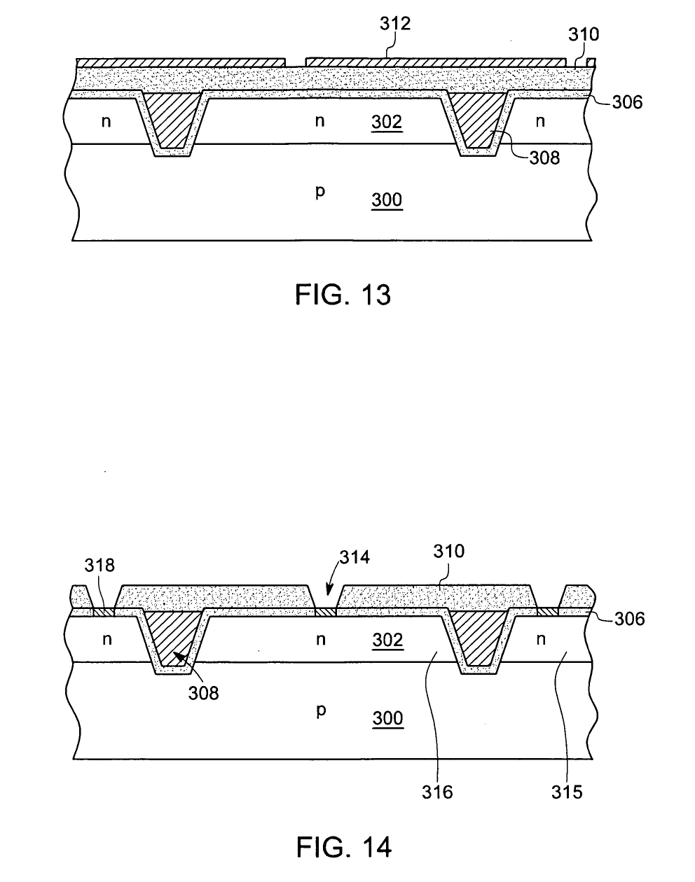

A second layer of an insulating material 310 is then disposed over the device structure, as shown in FIG. 13. The second insulating layer material may comprise a glass, as described earlier with regard to the insulating layer 306, or may be any other commonly used dielectric material like silicon dioxide. A patterned photoresist layer 312 is then formed using photolithography over the insulating layer 310. The openings in the photoresist layer, as shown in FIG. 13 form future locations for source and drain contacts.

FIG. 14 is a cross-sectional view of the device after etching and subsequent removal of the photoresist layer 312. The exposed regions of the second layer of insulating material 310 and first insulating layer 306 are removed simultaneously by etching to form the windows 314. The photoresist layer 312 is then removed to form the device structure shown in FIG. 14. The windows 314 extend through the second insulating layer 310 and through the first insulating layer 306 to access drain region 315 and source region 316. To facilitate conductive contact to the drain region 315 and source region 316, sintered contact metal 318, such as nickel is deposited in each window 314 as shown in FIG. 14. The metal deposition includes sequential steps of masking, sputtering and etching away the unwanted layers. The gate region of the device includes the p-doped SiC layer, the gate insulating layer and the gate metal. The area under the gate region is known as the channel of a MOSFET. In one embodiment of the present invention, the gate dielectric material (i.e., insulating layer 306) may be selected from a group of materials, such as glasses and ceramics, including but not limited to borosilicate, phosphosilicate and oxides of arsenic, aluminum, antimony or germanium in combination with SiO₂.

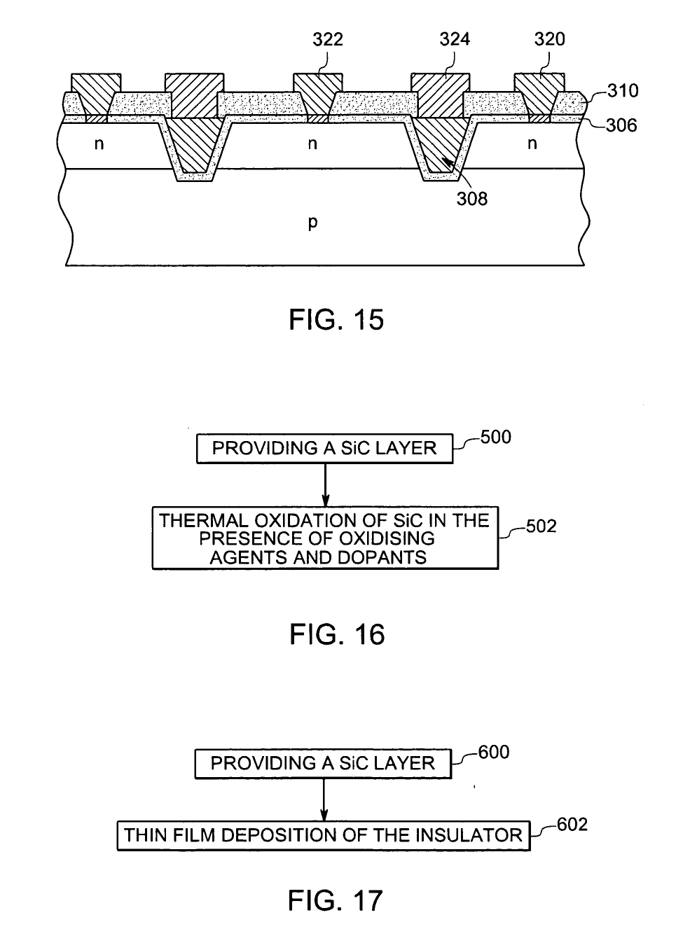

FIG. 15 illustrates the formation of drain contact 320, source contact 322 and gate contact 324 of a SiC MOSFET by a metallization pattern. In one embodiment, the metallization pattern of the contacts 320, 322 and 324 is formed using standard techniques of masking and etching, in a sequential manner, as discussed previously. As will be appreciated, a passivation layer (not shown) may also be disposed over the above structure to protect the surface against mechanical forces and environmental contamination resulting from handling. The passivation material, maybe selected from a group including but not limited to borosilicate glass, phosphosilicate glass and oxides of arsenic, antimony or germanium in combination with SiO₂.

FIG. 16 is a flow chart illustrating a method of fabricating a silicon carbide semiconductor device according to one embodiment of the present invention. The method comprises a first step 500 of providing a SiC layer. The SiC may be of 3C or 4H or 6H polytypic form.

The step 502 includes thermal oxidation of the SiC layer to form a thin layer of insulating oxide over the SiC layer. The thermal oxidation is carried out at temperatures of about 1000° C. to about 1300° C. in the presence of oxidizing agents. Non-limiting examples of oxidizing agents include oxygen, nitric oxide (NO) and nitrous oxide (N₂O).

The thermal oxidation of the SiC layer further includes subsequent annealing at high temperature. The annealing is carried out in the presence of an inert or oxidizing ambient such as NO or N₂O or nitrogen. The annealing involves heating the thermally oxidized SiC layer at high temperature with subsequent cooling. The cooling will induce stress at the interface of the insulating layer and the SiC layer, which may produce undesirable electrical properties and failure modes. In accordance with embodiments of the invention, the thermal expansion coefficient of the insulating material is tailored to match that of SiC to reduce stress at the interface.

In one embodiment, the thermal oxidation is carried out in the presence of glass or ceramic forming agents to match the thermal expansion coefficients of the SiC layer and the insulating layer. The amount of glass or ceramic forming agents can be controlled by the flow rate of the agents during the oxidation process to obtain the desired thermal expansion coefficient matched insulating layer. In another embodiment, a graded or a layered structure may be incorporated in the insulating layer by turning on and off the flow during thermal oxidation. A graded structure is wherein the thermal expansion coefficient of the insulating material varies within the insulating layer. A layered structure includes a number of layers of differing TEC.

The glass forming agents, for example may include silane and oxygen in combination with phosphine (PH₃), borane (BH₃), diborane (B₂H₆), trimethyl borate (B(OCH₃)₃), trimethyl phosphate ((CH₃)₃PO₄), phosphorus oxychloride (POCl₃) and oxides. The oxides that may be used to form the insulating layer include phosphorus pentoxide (P₂O₅), phosphorus trioxide (P₂O₃), and diboron trioxide (B₂O₃). The ceramic forming agents, for example, may include oxides of arsenic, oxides of aluminum, oxides of antimony, and oxides of germanium. The glass forming agents produce the respective oxides which in combination with silica form silicates resulting in a glassy layer or an insulating layer. A borosilicate glass insulating layer is formed by introducing desired quantity of B₂O₃ or B₂O₆ or any other boron containing glass forming agents and combinations thereof Likewise, a phosphosilicate glass layer may be provided over the SiC layer by introducing phosphine or POCl₃ to form [P₂O₅:SiO₂] during thermal oxidation. Introducing combinations of the boron and phosphorus containing glass forming agents may form a boro phospho silicate glass insulating layer. Alternatively, these layers can be deposited using silane SiH₄, phosphine PH₃, and oxygen either before or after thermal oxidation of the SiC using any of a number of oxidizing agents such as oxygen, nitrous oxide, or nitric oxide. Subsequent annealing of the layers merges the layers into a dielectric of appropriate coefficient of thermal expansion.

The addition of some of the glass forming agents, for example, phosphine (PH₃) is known to increase the oxidation rate, and in turn the growth rate. The growth rate is also dependent on the temperature at which the oxidation is carried out. So, while maintaining the same growth rate as in the case of undoped glass one may reduce the temperature required for oxidation in the case of doped glasses. The increased growth rate of the doped glasses may thus lower the temperature required to perform the oxidation and reduce stress at the interface resulting from thermal expansion coefficient mismatch.

FIG. 17 is a flow chart depicting another method of fabricating a SiC semiconductor device in accordance with an embodiment of the present invention. The method involves providing a SiC layer in step 600 and an insulating material layer is disposed over the SiC layer by thin film deposition in step 602. In one embodiment of the invention, a phosphosilicate glass layer is formed over the SiC layer by chemical vapor deposition at a temperature of about 450° C. followed by annealing in nitrogen at a temperature of about 925° C. for a period of about 30 minutes and similarly other glasses may be deposited using this technique.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A semiconductor device comprising:
at least one silicon carbide layer; and
an insulating layer disposed over the silicon carbide layer, wherein the insulating layer comprises glass or ceramic material.

2. The semiconductor device of claim 1, wherein the glass material comprises borosilicate glass or phosphosilicate glass.

3. The semiconductor device of claim 1, wherein the ceramic material comprises an oxide of aluminum, an oxide of arsenic, an oxide of antimony or an oxide of germanium in combination with SiO₂ and any combinations thereof.

4. The semiconductor device of claim 1, the device comprising a MOSFET or an integrated circuit or an electrooptical device or an insulated gate bipolar transistor or any combinations thereof.

5. The semiconductor device of claim 1, the device comprising a MOSFET device, wherein the insulating layer comprises a gate dielectric layer.

6. The semiconductor device of claim 1, the device comprising a MOSFET device, wherein the silicon carbide layer comprises a channel layer.

7. A semiconductor device comprising:
a silicon carbide layer; and
an insulating material layer disposed over the silicon carbide layer, wherein a thermal expansion coefficient of the insulating material is matched to a thermal expansion coefficient of the silicon carbide to reduce stress at a silicon carbide layer-insulating material layer interface.

8. The semiconductor device of claim 7, wherein the silicon carbide layer comprises a plurality of silicon carbide layers.

9. The semiconductor device of claim 7, wherein the insulating material layer comprises a graded or a layered structure.

10. The semiconductor device of claim 7, wherein the insulating material comprises a glass material or a ceramic material.

11. The semiconductor device of claim 7, wherein the insulating material comprises a borosilicate glass, or a phosphosilicate glass or an oxide of arsenic, antimony or germanium in combination with SiO₂ or any combinations thereof.

12. The semiconductor device of claim 7, wherein the thermal expansion coefficient of the insulating material is in a range of about 2×10⁻⁶/K to about 9×10⁻⁶/K.

13. The semiconductor device of claim 7, wherein the thermal expansion coefficient of the insulating material is in a range of about 3×10⁻⁶/K to about 7×10⁻⁶/K.

14. The semiconductor device of claim 7, wherein the thermal expansion coefficient of the insulating material is in a range of about 4×10⁻⁶/K to about 6×10⁻⁶/K.

15. The semiconductor device of claim 7, the device comprising a MOSFET or an integrated circuit or an electrooptical device or an insulated gate bipolar transistor or any combinations thereof.

16. The semiconductor device of claim 7, the device comprising a MOSFET device, wherein the silicon carbide layer comprises a channel layer.

17. The semiconductor device of claim 7, the device comprising a MOSFET device, wherein the insulating material layer comprises a gate dielectric layer.

18. A method of fabricating a silicon carbide device comprising:
providing a silicon carbide layer; and
providing an insulating layer over the silicon carbide layer; wherein the insulating layer comprises a glass material or a ceramic material.

19. The method of claim 18, wherein providing the insulating layer comprises:
thermally oxidizing the silicon carbide layer; and
annealing the silicon carbide layer in an inert or oxidizing ambient.

20. The method of claim 19, wherein thermally oxidizing the silicon carbide layer comprises thermally oxidizing the silicon carbide layer in presence of glass forming agents or ceramic forming agents.

21. The method of claim 20, wherein the glass forming agents and ceramic forming agents comprise materials comprising phosphine, borane, diborane, trimethyl borate, trimethyl phosphate, phosphorus oxychloride, gaseous compounds of arsenic, aluminum, antimony, germanium and any combinations thereof.

22. The method of claim 18, wherein providing the insulating layer comprises depositing a thin film insulating layer.

23. The method of claim 22, wherein depositing the thin film comprises chemical vapor deposition, or laser assisted molecular beam deposition, or plasma enhanced chemical vapor deposition or sputtering or any combinations thereof.

24. The method of claim 22, wherein depositing the thin film further comprises using glass forming agents or ceramic forming agents comprising borane, diborane, phosphine, trimethyl borate, trimethyl phosphate, phosphorus oxychloride, oxides of arsenic, aluminum, antimony, germanium and any combinations thereof.

25. The method of claim 18, further comprising modifying a thermal expansion coefficient of the insulating layer to match a thermal expansion coefficient of the silicon carbide layer.

26. The method of claim 18, wherein the insulating layer comprises a graded structure or a layered structure.

27. The method of claim 18, further comprising:
providing a plurality of layers of silicon carbide;
patterning the silicon carbide to form a plurality of gate region grooves;
filling the plurality of gate region grooves with the insulating material;
patterning to form the source and drain regions; and
providing a plurality of metal contact layers.
